(19) United States
(12) Patent Application Publication
(10) Pub. No.: US 2014/0258667 A1
(43) Pub. Date: Sep. 11, 2014

(54) Apparatus and Method for Memory Operation Bonding

(71) Applicant: MIPS TECHNOLOGIES, INC., Sunnyvale, CA (US)

(72) Inventor: Ranganathan Sudhakar, Santa Clara, CA (US)

(73) Assignee: MIPS TECHNOLOGIES, INC., Sunnyvale, CA (US)

(21) Appl. No.: 13/789,394

(22) Filed: Mar. 7, 2013

(51) Int. Cl. G11C 7/10

(52) U.S. Cl. CPC G11C 7/1039
USPC 711/169

(57) ABSTRACT

A processor is configured to evaluate memory operation bonding criteria to selectively identify memory operation bonding opportunities within a memory access plan. Memory operations are combined in response to the memory operation bonding opportunities to form a revised memory access plan with accelerated memory access.

### FIELD OF THE INVENTION

This invention relates generally to computer architectures. More particularly, this invention relates to processor architectures with memory operation bonding.

### BACKGROUND OF THE INVENTION

High performance processors typically need to issue more than one load or store instruction per cycle. This requires a lot of hardware resources such as instruction schedulers, data buffers, translation look-aside buffers (TLBs) and replicated tag/data memories in the data cache, which drives up power consumption and area requirements, which is problematic. This is problematic in any microprocessor, but is particularly problematic in power-constrained applications, such as embedded processors or server machines.

Most superscalar processors have three or four processing channels, i.e., they can dispatch three to four instructions every cycle. Around 40% of instructions can be memory operations. Thus, optimization of memory operations across multiple processing channels can lead to significant efficiencies.

### SUMMARY OF THE INVENTION

A processor is configured to evaluate memory operation bonding criteria to selectively identify memory operation bonding opportunities within a memory access plan. Combined memory operations are created in response to the memory operation bonding opportunities to form a revised memory access plan with accelerated memory access.

A non-transitory computer readable storage medium includes executable instructions to define a processor configured to evaluate memory operation bonding criteria to selectively identify memory operation bonding opportunities within a memory access plan. Combined memory operations are created in response to the memory operation bonding opportunities to form a revised memory access plan with accelerated memory access.

### BRIEF DESCRIPTION OF THE FIGURES

The invention is more fully appreciated in connection with the following detailed description taken in conjunction with the accompanying drawings, in which:

FIG. 1 illustrates a processor configured in accordance with an embodiment of the invention.

Like reference numerals refer to corresponding parts throughout the several views of the drawings.

### DETAILED DESCRIPTION OF THE INVENTION

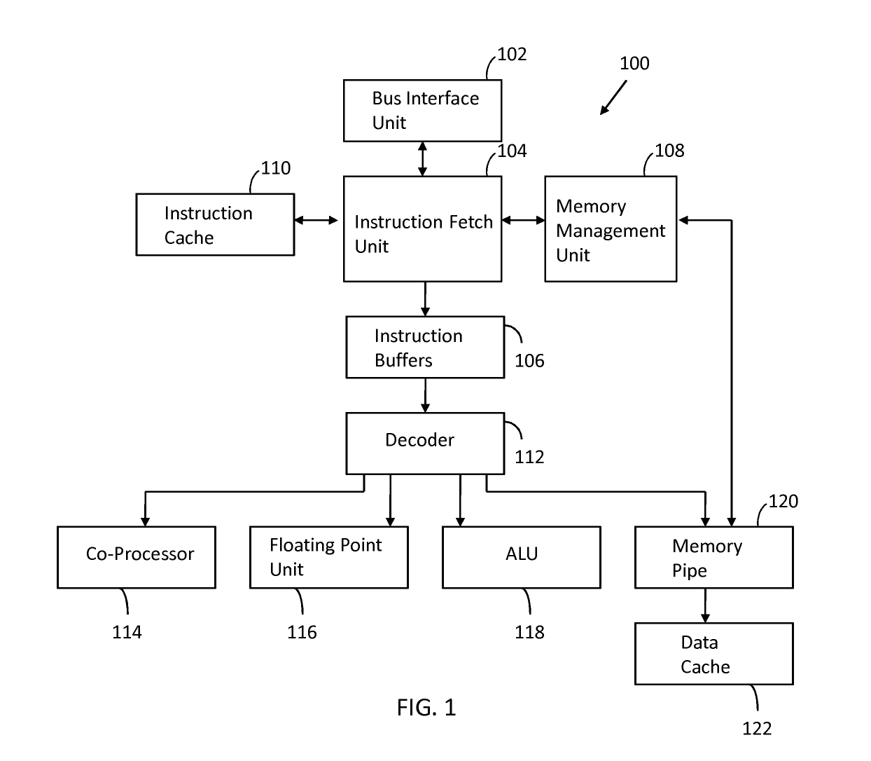

FIG. 1 illustrates a processor 100 configured in accordance with an embodiment of the invention. The processor 100 implements memory bonding operations described herein. In particular, the processor implements run time bonding of adjacent memory operations to effectively form a single instruction multiple data (SIMD) instruction from a non-SIMD instruction set. This facilitates wider and fewer memory accesses.

The processor 100 includes a bus interface unit 102 connected to an instruction fetch unit 104. The instruction fetch unit 104 retrieves instructions from an instruction cache 110. The memory management unit 108 provides virtual address to physical address translations for the instruction fetch unit 104. The memory management unit 108 also provides load and store data reference translations for the memory pipe (load-store unit) 120.

Fetched instructions are applied to instruction buffers 106. The decoder 112 accesses the instruction buffers 106. The decoder 112 is configured to implement dynamic memory operation bonding. The decoder 112 applies a decoded instruction to a functional unit, such as a co-processor 114, a floating point unit 116, an arithmetic logic unit (ALU) 118 or a memory 120 pipe, which processes load and store addresses to access a data cache 122.

The decoder 112 is configured such that multiple memory operations (to adjacent locations) are “bonded” or coupled together after instruction decode. The bonded memory operations execute as one entity during their lifetime in the core of the machine. For example, two 32-bit loads may be bonded into one 64-bit load. The bonded operation requires wider datapaths (e.g., 64-bit rather than 32-bit), which may be already be resident on the machine. Even if a wider channel is not available, two 32-bit memory pipelines are vastly lower area and power than one 64-bit operation. Thus, the invention forms a revised memory access plan with accelerated memory access. The accelerated access may result from a wider data channel than the data channel utilized by the original memory access plan. Alternately, the accelerated access may result from a pipelined memory access. For example, the memory pipe 120 may utilize a 64-bit channel to access data cache 122. Alternately, the memory pipe 120 may utilize a pipelined memory access to the data cache 122.

Thus, the invention allows for the creation of high-performance machines that are still very efficient, compared to the known prior art. In some sense, this bonding of multiple memory operations into one wider operation can be thought of as creating SIMD instructions dynamically from a non-SIMD instruction stream. In other words, the SIMD functionality is not contemplated by the instruction set or the computer architecture. Rather, SIMD-type opportunities are identified in a code base that does not have SIMD instructions and does not otherwise contemplate SIMD functionality.

As indicated above, around 40% of instructions can be memory operations. This implies that around 1.2 to 1.6 load/store instructions may need to be accommodated per cycle for a four channel processor. Thus, the memory bonding operations of the invention may be widely utilized. Further, many common program subroutines, such as memory copy, byte zero or string comparisons require a high rate of load/store accesses to the first-level data cache, offering additional opportunities to exploit the techniques of the invention.

Providing more than one load/store port to cache is a very expensive proposition—requiring more scheduler resources, register file read and write ports, address generators, tag arrays, tag comparators, translation look-aside buffers, data arrays, store buffers, memory forwarding and disambiguation logic. However, in many situations where one needs to execute more than one load (or store) per cycle, one finds that the data being accessed is contiguous in the memory and further, is accessed by adjacent instructions in the program memory (code stream). The processor 100 is configured to recognize and take advantage of this by converting the majority of such critical back-to-back memory accesses to fewer but wider accesses that can execute with minimal area or power overhead thanks to minimal additional hardware. As a result, the processor 100 facilitates vast improvements in performance (50% to 100%) on key routines.

Consider the following code:

| | | |
|---|---|---|
| LW | r5, Offset_1(r20) | //32 bit load from register 5 to a first position in |
| | | //register 20 |
| LW | r6, Offset_2(r20) | //Adjacent 32 bit load from register 6 to a |
| | | //second position in register 20 |

This code constitutes a memory access plan. As used herein, a memory access plan is a specification of memory access operations. The memory access plan contemplates a single memory access channel. This code is dynamically evaluated to create a bonded memory operation. That is, memory operation bonding criteria are used to evaluate the code to selectively identify memory operation bonding opportunities within the memory access plan. If a memory operation bonding opportunity exists, combined memory operations are formed to establish a revised memory access plan with accelerated memory access. In this instance, the revised memory access plan is coded as follows:

| LW2 | (r5, r6), Offset_1(r20) | //Bonded 64 bit load from register 5 and |
|---|---|---|
| | | //register 6 to a first position in register |
| | | //20 |

In this example, each adjacent pair of 32-bit memory instructions is bonded into one 64-bit operation. Most 32-bit processors already have 64-bit datapaths to the data cache, since they must support 64-bit floating-point loads and stores. However, it is a relatively trivial matter to widen the memory pipeline from 64-bits to 32-bits for those 32-bit processors that do not already have 64-bit datapaths to/from the cache.

In general, the technique is not limited to bonding two 32-bit operations into 64-bit operations. It can be equally well applied to bonding two 64-bit operations into a single 128-bit operation or four 32-bit memory operations into one 128-bit operation, with attendant benefits in performance, area and power.

Various memory operation bonding criteria may be specified. For example, memory operation bonding criteria may include: adjacent load or store instructions, same memory type for two memory operations, same base address register for two memory operations, consecutive memory locations, displacement differing by access size and in the case of loads, the destination of the first operation is not a source for the second operation. Another condition may require an aligned address after bonding.

Hardware solutions to the problem of scaling memory issue width without incurring large area/power costs are illusive. Software approaches to the problem require new instructions, making the benefits inaccessible to existing code. This also requires changes to the software ecosystem; such changes are difficult to deploy. Also, a potential software solution might require the hardware to perform misaligned memory accesses since the software cannot know the alignment of all operations at compile time. The bonding technique can be used in conjunction with a bonding predictor to ensure that all bonded accesses are aligned, which is an important and desirable feature of pure RISC architectures. Thus, such a scheme can work well at runtime, when hardware can see the actual addresses generated by memory operations. Processors that do handle misaligned addresses in hardware can still use this technique and obtain greater performance gains.

Those skilled in the art will appreciate that the invention elegantly solves a vexing problem in processor design and has broad applicability to any general-purpose processor, irrespective of issue width, pipeline depth or degree of speculative execution. Advantageously, the techniques of the invention require no change in the instruction set. Consequently, the techniques are applicable to all existing binaries.

While various embodiments of the invention have been described above, it should be understood that they have been presented by way of example, and not limitation. It will be apparent to persons skilled in the relevant computer arts that various changes in form and detail can be made therein without departing from the scope of the invention. For example, in addition to using hardware (e.g., within or coupled to a Central Processing Unit (“CPU”), microprocessor, microcontroller, digital signal processor, processor core, System on chip (“SOC”), or any other device), implementations may also be embodied in software (e.g., computer readable code, program code, and/or instructions disposed in any form, such as source, object or machine language) disposed, for example, in a computer usable (e.g., readable) medium configured to store the software. Such software can enable, for example, the function, fabrication, modeling, simulation, description and/or testing of the apparatus and methods described herein. For example, this can be accomplished through the use of general programming languages (e.g., C, C++), hardware description languages (HDL) including Verilog HDL, VHDL, and so on, or other available programs. Such software can be disposed in any known non-transitory computer usable medium such as semiconductor, magnetic disk, or optical disc (e.g., CD-ROM, DVD-ROM, etc.). It is understood that a CPU, processor core, microcontroller, or other suitable electronic hardware element may be employed to enable functionality specified in software.

It is understood that the apparatus and method described herein may be included in a semiconductor intellectual property core, such as a microprocessor core (e.g., embodied in HDL) and transformed to hardware in the production of integrated circuits. Additionally, the apparatus and methods described herein may be embodied as a combination of hardware and software. Thus, the present invention should not be limited by any of the above-described exemplary embodiments, but should be defined only in accordance with the following claims and their equivalents.

1. A processor configured to:
evaluate memory operation bonding criteria to selectively identify memory operation bonding opportunities within a memory access plan; and
create combined memory operations in response to the memory operation bonding opportunities to form a revised memory access plan with accelerated memory access.

2. The processor of claim 1 wherein the revised memory access plan utilizes a wider data channel than the data channel utilized by the memory access plan.

3. The processor of claim 1 wherein the revised memory access plan utilizes a pipelined memory access.

4. The processor of claim 1 wherein the memory operation bonding criteria specifies adjacent load or store instructions.

5. The processor of claim 1 wherein the memory operation bonding criteria specifies a common memory type for two memory operations.

6. The processor of claim 1 wherein the memory operation bonding criteria specifies a common base address register for two memory operations.

7. The processor of claim 1 wherein the memory operation bonding criteria specifies consecutive memory locations.

8. The processor of claim 1 wherein the memory operation bonding criteria specifies displacement differing by access size.

9. The processor of claim 8 wherein the memory operation bonding criteria specifies that in the case of loads, the destination of the first memory operation is not a source for the second memory operation.

10. The processor of claim 1 wherein the memory operation bonding criteria specifies an aligned address after bonding.

11. A non-transitory computer readable storage medium comprising executable instructions to define a processor configured to:
evaluate memory operation bonding criteria to selectively identify memory operation bonding opportunities within a memory access plan; and
create combined memory operations in response to the memory operation bonding opportunities to form a revised memory access plan with accelerated memory access.

12. The non-transitory computer readable storage medium of claim 11 wherein the revised memory access plan utilizes a wider data channel than the data channel utilized by the memory access plan.

13. The non-transitory computer readable storage medium of claim 11 wherein the revised memory access plan utilizes a pipelined memory access.

14. The non-transitory computer readable storage medium of claim 11 wherein the memory operation bonding criteria specifies adjacent load or store instructions.

15. The non-transitory computer readable storage medium of claim 11 wherein the memory operation bonding criteria specifies a common memory type for two memory operations.

16. The non-transitory computer readable storage medium of claim 11 wherein the memory operation bonding criteria specifies a common base address register for two memory operations.

17. The non-transitory computer readable storage medium of claim 11 wherein the memory operation bonding criteria specifies consecutive memory locations.

18. The non-transitory computer readable storage medium of claim 11 wherein the memory operation bonding criteria specifies displacement differing by access size.

19. The non-transitory computer readable storage medium of claim 18 wherein the memory operation bonding criteria specifies that in the case of loads, the destination of the first memory operation is not a source for the second memory operation.

20. The non-transitory computer readable storage medium of claim 11 wherein the memory operation bonding criteria specifies an aligned address after bonding.
